(19) United States
(12) Patent Application Publication
(10) Pub. No.: US 2026/0127330 A1
(43) Pub. Date: May 7, 2026

(54) APPARATUS, METHOD, AND NON-TRANSITORY COMPUTER-READABLE MEDIUM THAT PREPARE ENERGY FLOW DIAGRAM

(71) Applicant: Yokogawa Electric Corporation, Tokyo (JP)

(72) Inventor: Akihisa KAWAMURA, Tokyo (JP)

(21) Appl. No.: 19/365,065

(22) Filed: Oct. 21, 2025

(30) Foreign Application Priority Data
Nov. 1, 2024 (JP) 2024-193056

(51) Int. Cl. G06F 30/18; G06Q 50/06

(52) U.S. Cl. CPC G06F 30/18; G06Q 50/06

(57) ABSTRACT

There is provided an apparatus including a processor, in which the processor acquires information of a layout diagram in relation to one or more pieces of energy equipment which generate or consume energy and one or more energy transmission paths which are connected to the energy equipment, selects equipment to be included in a first energy flow diagram, from the layout diagram, and prepares, based on the selected equipment, the first energy flow diagram which shows the energy equipment, the energy transmission path, and one or more pieces of metering equipment which measure parameters in relation to the energy.

The contents of the following patent application (s) are incorporated herein by reference: NO. 2024-193056 filed in JP on November 1, 2024.

### BACKGROUND

### 1. TECHNICAL FIELD

The present invention relates to an apparatus, a method, and a non-transitory computer-readable medium.

### 2. RELATED ART

Patent Document 1 discloses converting and displaying a processing flow of site data of a factory or the like according to the execution environments or requirements.

### RELATED ART DOCUMENTS

### Patent Document

Patent Document 1: Japanese Patent Application Publication No. 2018-181262

### BRIEF DESCRIPTION OF THE DRAWINGS

FIG. 1 shows a configuration example of a system 10 of the present embodiment.

FIG. 2 shows an example of an operation flow of a preparation apparatus 110 of the present embodiment.

FIG. 3 shows an example of a layout diagram 300 which is acquired by the preparation apparatus 110 of the present embodiment.

FIG. 4 shows an example of a branch layout diagram 400 which is acquired by the preparation apparatus 110 of the present embodiment.

FIG. 5 shows an example of a first energy flow diagram 500 which is prepared by the preparation apparatus 110 of the present embodiment.

FIG. 6 shows an example of a second energy flow diagram 600 which is prepared by the preparation apparatus 110 of the present embodiment.

FIG. 7 shows an example of an input point list 690 which is prepared by the preparation apparatus 110 of the present embodiment.

FIG. 8 is an example of a layout diagram 700 which schematically shows a single-line diagram.

FIG. 9 shows an example of a first energy flow diagram 800 which is prepared from the layout diagram 700 by the preparation apparatus 110 of the present embodiment.

FIG. 10 shows an example of a second energy flow diagram 900 which is prepared from the first energy flow diagram 800 by the preparation apparatus 110 of the present embodiment.

FIG. 11 shows an example of a computer 2200 in which a plurality of aspects of the present invention may be embodied entirely or partially.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

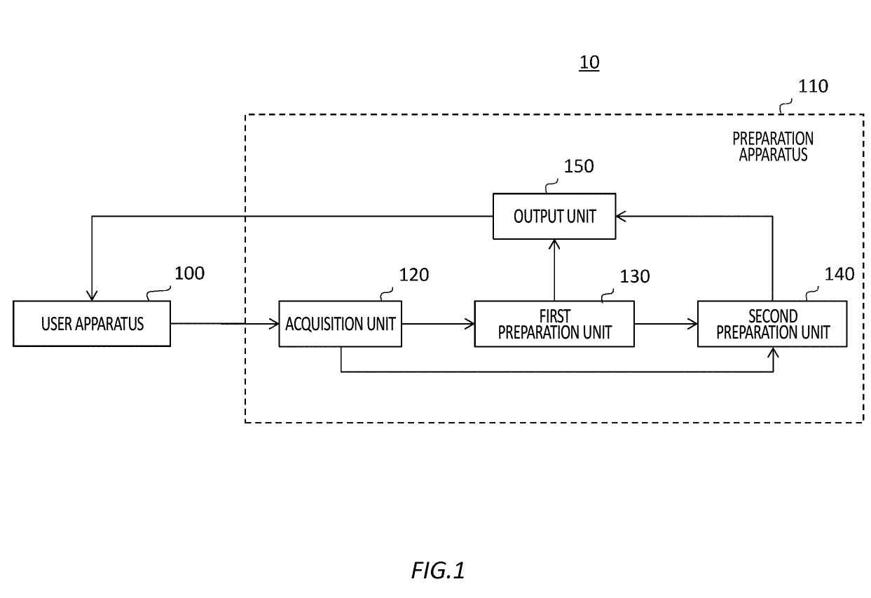

FIG. 1 shows a configuration example of a system 10 of the present embodiment. The system 10 prepares, for example, an energy flow diagram which displays a flow of energy in a plant. Here, examples of the plant include: in addition to an industrial plant such as a chemical plant, a plant for managing and controlling a well site such as a gas field or an oil field and its surrounding area; a plant for managing and controlling power generation such as hydroelectric, thermal, or nuclear power generation; a plant for managing and controlling energy harvesting from solar power, wind power, or the like; a plant for managing and controlling water and sewerage, dams, or the like; and others. In addition, the system 10 may prepare, for example, an energy flow diagram which displays a flow of energy in a factory that produces, for example, food, electronic parts, or the like. In addition, the energy may be, for example, electricity, fuel, steam, heat, compressed air, or another similar medium. The system 10 includes a user apparatus 100 and a preparation apparatus 110.

The user apparatus 100 may be at least one of a terminal such as a smartphone and a personal computer, a display apparatus such as a display, or an input apparatus such as a mouse and a keyboard, which are used by one or more users. The user apparatus 100 receives an input of information from a user, and also displays the energy flow diagram.

The preparation apparatus 110 may be a computer such as a PC, a tablet type computer, a smartphone, a workstation, a server computer, or a general purpose computer, or may be a computer system in which a plurality of computers are connected. Such a computer system is also a computer in a broad sense. In addition, the preparation apparatus 110 may be implemented by one or more virtual computer environments which are able to be run in the computer. Instead of this, the preparation apparatus 110 may be a dedicated computer designed to prepare the energy flow diagram, or may be dedicated hardware realized by a dedicated circuit. When the computer is used, the preparation apparatus 110 is realized by executing a program by the computer.

The preparation apparatus 110 includes an acquisition unit 120, a first preparation unit 130, a second preparation unit 140, and an output unit 150. The acquisition unit 120 is connected to the user apparatus 100, and acquires the information from one or more users via the user apparatus 100. The acquisition unit 120 acquires, from the user apparatus 100, the information of a layout diagram in relation to one or more pieces of energy equipment which generate or consume energy and one or more energy transmission paths which are connected to the energy equipment. The layout diagram may further show one or more pieces of metering equipment which measure parameters in relation to the energy.

Here, at least one of the pieces of energy equipment is, as an example, a distribution board that distributes power from a power system; a compressor that supplies a gas or air from a gas tank or the like; a transformer; a lighting equipment that consumes electricity; production equipment including a motor or the like; or an air conditioning equipment including an air conditioner or the like. The metering equipment is, as an example, a measuring instrument or the like that measures an amount of energy consumption or an amount of energy outputs, an energy cost, an amount of CO₂ emissions, energy efficiency, or the like in the corresponding energy equipment. The metering equipment may be arranged to be adjacent to an input side or an output side of the corresponding energy equipment, in the energy transmission path. The energy transmission path is, for example, piping (as an example, gas piping or the like) or wiring (as an example, an electric wire or the like) that transmits the energy between a plurality of pieces of energy equipment. The information of the layout diagram may be data, an image, or the like showing a layout of a connection relationship or the like between the energy equipment and the energy transmission path.

The first preparation unit 130 is connected to the acquisition unit 120. The first preparation unit 130 selects equipment to be included in a first energy flow diagram, from the layout diagram; and prepares, based on the selected equipment, the first energy flow diagram which shows the energy equipment, the energy transmission path, and one or more pieces of metering equipment which measure parameters in relation to the energy. The first energy flow diagram may be a diagram showing the flow of the energy in the metering equipment, the energy equipment, and the energy transmission path. Here, the metering equipment, the energy equipment, and the energy transmission path are also simply referred to as "equipment".

The second preparation unit 140 is connected to the acquisition unit 120 and the first preparation unit 130. The second preparation unit 140 prepares a second energy flow diagram, based on a user input to the first energy flow diagram, and the first energy flow diagram. The second preparation unit 140 may acquire, via the acquisition unit 120, the user input to the first energy flow diagram prepared by the first preparation unit 130. The second energy flow diagram is a diagram showing the flow of energy through the metering equipment, the energy equipment, and the energy transmission path; and may show more detailed information of the equipment than the first energy flow diagram. The second energy flow diagram may be an energy flow diagram for a FEMS (Factory Energy Management System). It should be noted that the user input may be various types of information that are input from the user to the preparation apparatus 110 via the user apparatus 100 or the like.

The output unit 150 is connected to the first preparation unit 130 and the second preparation unit 140. The output unit 150 may output and display, to the user apparatus 100, each of the first energy flow diagram prepared by the first preparation unit 130 and the second energy flow diagram prepared by the second preparation unit 140.

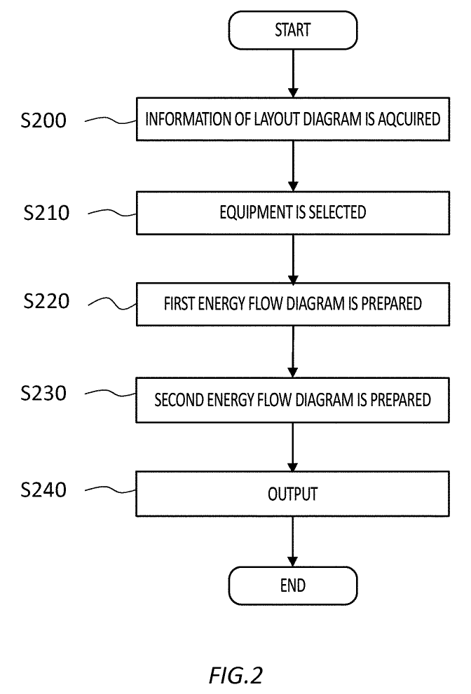

FIG. 2 shows an example of an operation flow of the preparation apparatus 110 of the present embodiment. In S200, the acquisition unit 120 acquires the information of the layout diagram from the user apparatus 100. The acquisition unit 120 may acquire electronic data (as an example, CAD data or the like) by which the preparation apparatus 110 is able to identify each of the configurations including the energy equipment, the metering equipment, and the energy transmission path in the layout diagram. In addition, the acquisition unit 120 may acquire the electronic data of the layout diagram, by identifying each piece of equipment in the layout diagram by an image recognition or the like, for the image of the layout diagram captured by a camera or a scanner. The acquisition unit 120 may acquire a plurality of layout diagrams which are related to each other. The acquisition unit 120 may acquire a plurality of layout diagrams respectively showing a plurality of divided regions in the plant. The acquisition unit 120 may acquire such plurality of layout diagrams in association with each other (for example, acquiring the plurality of layout diagrams by associating the same identification number, or acquiring the plurality of layout diagrams of the same acquisition time in association with each other, or the like).

The acquisition unit 120 may acquire the user input to the layout diagram from the user apparatus 100, together with the layout diagram. The acquisition unit 120 may acquire the user input specifying the information for each configuration in the layout diagram. The acquisition unit 120 may acquire, from the user, the information specifying a position (position in the layout diagram) of existing metering equipment which is not shown in the layout diagram but is actually arranged.

The acquisition unit 120 may acquire marks for the energy equipment, the metering equipment, and the energy transmission path in the layout diagram by the user input. The acquisition unit 120 may acquire a mark indicating the information such as a type, a general name, and an identifier of each piece of energy equipment, in association with the corresponding energy equipment in the layout diagram. The acquisition unit 120 may acquire a mark indicating the information such as a measurement target and a general name of the metering equipment, in association with the corresponding metering equipment in the layout diagram. The acquisition unit 120 may acquire a mark indicating a branch position of the energy transmission path, a flow direction of the energy, or the like (as an example, an identifier of a branch, an arrow indicating the flow direction, or the like) in association with a position of the corresponding energy transmission path in the layout diagram. The acquisition unit 120 may acquire a mark indicating a partial region, in the layout diagram, which is converted into the first energy flow diagram. It should be noted that the acquisition unit 120 may acquire the data of the layout diagram to which a mark is attached.

The acquisition unit 120 may acquire the data of a branch layout diagram indicating only the energy transmission path and the identifier of the branch, together with the layout diagram. The user can specify the layout of the first energy flow diagram by the branch layout diagram.

In S210, the first preparation unit 130 selects the equipment to be included in the first energy flow diagram, based on the user input. The first preparation unit 130 may select the energy equipment, the energy transmission path, and the metering equipment in the layout diagram. The first preparation unit 130 may select the energy equipment, the energy transmission path, and the metering equipment which are associated with marks in the layout diagram. The first preparation unit 130 may select the energy transmission path connected to the energy equipment associated with a mark, and the energy equipment and the metering equipment which are connected to branches associated with marks. When a specification of a selection range of a part of the layout diagram is received by the user input, the first preparation unit 130 may select the energy equipment, the energy transmission path, and the metering equipment within the specified selection range.

The first preparation unit 130 may select the energy equipment, the energy transmission path, and the metering equipment from the plurality of layout diagrams, to prepare one first energy flow diagram from the plurality of layout diagrams associated by the acquisition unit 120. For example, in the plurality of layout diagrams, the first preparation unit 130 may select the equipment to which a common mark is attached, as the equipment to be included in the first energy flow diagram. In the plurality of layout diagrams, the first preparation unit 130 may select the equipment to which a common mark is attached (at least one of the energy equipment, the energy transmission path, or the metering equipment), as the same equipment. In the plurality of layout diagrams, the first preparation unit 130 may select the equipment with which the same identifier or the same equipment name is associated (that is, the equipment duplicated in the plurality of layout diagrams), as the same equipment.

In S220, the first preparation unit 130 prepares the first energy flow diagram showing the information of the energy equipment, the energy transmission path, and the metering equipment which are selected. The first preparation unit 130 may prepare the first energy flow diagram by maintaining the connection relationship between the energy equipment, the energy transmission path, and the metering equipment in the layout diagram. The first preparation unit 130 may prepare the first energy flow diagram in which figures(a block, a line, and the like) indicating the energy equipment, the energy transmission path, and the metering equipment are arranged along the direction of the energy flow (as an example, for the flow direction of the energy to be a direction from a right to a left or from the left to the right in the first energy flow diagram). The first preparation unit 130 may use a figure predetermined for each piece of equipment in the first energy flow diagram. The first preparation unit 130 may prepare the first energy flow diagram in accordance with the layout diagram and the user input to the layout diagram. The first preparation unit 130 may prepare the first energy flow diagram to indicate the information specified by a mark. In the first energy flow diagram, the first preparation unit 130 may indicate a type of the energy equipment; draw the energy transmission path with a line; and indicate the branch of the energy transmission path with an identifier. The first preparation unit 130 may prepare the first energy flow diagram, according to the layout of the branch of the branch layout diagram acquired by the acquisition unit 120.

The first preparation unit 130 may combine pieces of equipment to which a common mark is attached in the plurality of layout diagrams acquired in association by the acquisition unit 120, and prepare the first energy flow diagram. The first preparation unit 130 may prepare one first energy flow diagram in which the plurality of layout diagrams are combined, by combining pieces of equipment to which a common mark is attached. For example, in the first energy flow diagram, the first preparation unit 130 may indicate the energy equipment to which a mark of the same identifier is attached in the plurality of layout diagrams, as one piece of energy equipment. In this way, the first preparation unit 130 can identify the connection relationship between pieces of equipment in the plurality of layout diagrams, based on the equipment to which a common mark is attached, and can prepare one first energy flow diagram from the plurality of layout diagrams.

In the layout diagram, the first preparation unit 130 may extract the energy equipment for which the corresponding metering equipment is not installed, and prepare a proposal for one or more pieces of new metering equipment in the first energy flow diagram. In the layout diagram, as the energy equipment for which the corresponding metering equipment is not installed, the first preparation unit 130 may extract the energy equipment for which the metering equipment is not provided in a position adjacent to at least one of an upstream side (that is, an input side of the energy equipment) or a downstream side (that is, an output side of the energy equipment). As the energy equipment for which the corresponding metering equipment is not installed, the first preparation unit 130 may extract the energy equipment for which the metering equipment is not specified in a position adjacent to at least one of the upstream side or the downstream side, by the user input to the layout diagram. For example, the first preparation unit 130 may extract the energy equipment for which the metering equipment is not provided to measure a parameter in relation to the energy that is input to the energy equipment or that is output from the energy equipment. The first preparation unit 130 may prepare a proposal for arranging new metering equipment on at least one of the upstream side or the downstream side of the energy equipment. The first preparation unit 130 may prepare a proposal for new metering equipment which measures a parameter in relation to the energy that is input to the extracted energy equipment or that is output from the energy equipment. The first preparation unit 130 may make the proposal by indicating new metering equipment on the first energy flow diagram.

The first preparation unit 130 may prepare the proposal for new metering equipment, based on at least one of the information or an allowable cost of the extracted energy equipment. The first preparation unit 130 may prepare the proposal for new metering equipment such that at least one of the number of pieces of new metering equipment or an installation cost of each piece of new metering equipment does not exceed an allowable cost set in advance by the user. In addition, when the extracted energy equipment is predetermined equipment (a predetermined name or type, or the like), the first preparation unit 130 may prepare the proposal to provide new metering equipment at a predetermined position (at least one of the upstream side or the downstream side) for the energy equipment. The first preparation unit 130 may acquire a table, in advance by the user input, in which a priority of new metering equipment is prescribed for each piece of equipment, or for each of the upstream side and the downstream side of the equipment; and use the table to prepare the proposal. The first preparation unit 130 may propose the number of pieces of new metering equipment not exceeding an allowable cost in descending order of the priority.

The first preparation unit 130 may prepare the proposal for new metering equipment, based on at least one of another piece of the energy equipment which is connected to an input or an output of the extracted energy equipment, or the number of the branches of the energy transmission path which is connected to an input or an output of the extracted energy equipment. When the equipment connected to the upstream side or the downstream side of the extracted energy equipment is predetermined equipment (a predetermined name or type, or the like), the first preparation unit 130 may prepare the proposal to provide new metering equipment at a predetermined position (at least one of the upstream side or the downstream side) for the extracted energy equipment. When the number of the branches of the energy transmission path which is connected to the input or the output of the extracted energy equipment is greater than or equal to a predetermined threshold value, the first preparation unit 130 may prepare the proposal to provide new metering equipment between the extracted energy equipment and the branch.

The first preparation unit 130 may prepare the proposal for new metering equipment based on the number of a plurality of pieces of the extracted energy equipment of the same type which are connected in parallel. When the plurality of pieces of energy equipment which are connected in parallel from a common branch are of the same type, the first preparation unit 130 may prepare the proposal to provide the corresponding new metering equipment for each of the plurality of pieces of energy equipment connected in parallel, according to the number of pieces of the energy equipment connected in parallel being greater than or equal to a predetermined threshold value. Here, the first preparation unit 130 may set, as the energy equipment of the same type, the energy equipment which uses the energy of the same type or which has the same identification information (a general name, a product name, or the like). When an energy efficiency of even one of the plurality of pieces of energy equipment connected in parallel in this way is reduced, an overall energy efficiency is reduced, and thus by providing new metering equipment according to the proposal, the user can effectively determine the reduction in energy efficiency.

For the extracted plurality of pieces of energy equipment, the first preparation unit 130 may calculate a priority in accordance with the information of the energy equipment, and prepare the proposal to provide a predetermined number of pieces of new metering equipment for the corresponding energy equipment in descending order of the priority. The first preparation unit 130 may acquire, in advance from the user, a table indicating a priority in accordance with a type of energy equipment, and determine priorities of the plurality of pieces of energy equipment according to the table. In the table, the greater the energy consumption of the energy equipment is, the higher the priority may be set. The first preparation unit 130 may acquire, in advance from the user, a table indicating a priority in accordance with a type of another piece of the energy equipment which is connected to the input or the output of the extracted energy equipment, and respectively determine the priorities of the plurality of pieces of energy equipment according to the table. In the table, the greater the energy consumption of another piece of the energy equipment is, the higher the priority may be set. It should be noted that the priorities may be set for the upstream side and the downstream side of the energy equipment, respectively.

In addition, the first preparation unit 130 may determine a priority in accordance with the number of the branches included in the energy transmission path which is connected to the input or the output of the extracted energy equipment. As an example, the first preparation unit 130 may determine a higher priority as the number of the branches becomes greater. In addition, the first preparation unit 130 may determine a priority for each piece of energy equipment, in accordance with the number of the plurality of pieces of extracted energy equipment of the same type which are connected in parallel. As an example, the first preparation unit 130 may determine a higher priority as the number of pieces of energy equipment connected in parallel becomes greater. The first preparation unit 130 may respectively calculate a total of the plurality of priorities, for pieces of the extracted energy equipment. The first preparation unit 130 may prepare the proposal to provide a number of pieces of new metering equipment which do not exceed an allowable cost in descending order of the total of the priorities, at corresponding positions (for example, the upstream side, the downstream side of the corresponding energy equipment, or the like).

The first preparation unit 130 may use a learning model that outputs the proposal for new metering equipment according to the input of the information in relation to the energy equipment; and prepare the proposal for new metering equipment in accordance with the extracted energy equipment. The first preparation unit 130 may acquire the information in relation to the energy equipment from the electronic data (CAD data or the like) by which each configuration is able to be identified in the layout diagram, or the electronic data acquired by an image recognition from image data of the layout diagram. As the information in relation to the energy equipment, the first preparation unit 130 may use at least one of: a type of the energy equipment; a type of another piece of the energy equipment which is connected to the input or the output of the energy equipment; the number of the branches included in the energy transmission path which is connected to the input or the output of the energy equipment; or the number of the plurality of pieces of energy equipment of the same type which are connected in parallel. The first preparation unit 130 may acquire a priority that is output according to inputting the information in relation to the extracted energy equipment into the learning model. The first preparation unit 130 may prepare the proposal to provide a predetermined number of pieces of new metering equipment in descending order of the priority, at corresponding positions (for example, the upstream side, the downstream side of the corresponding energy equipment, or the like). In addition, the first preparation unit 130 may prepare the proposal according to a value (0 or 1) indicating whether or not to propose new energy equipment which is output according to inputting the information in relation to the energy equipment into the learning model.

The learning model that is used by the first preparation unit 130 may be a model generated by various types of machine learning algorithms including a random forest, gradient boosting, logistic regression, a neural network, and a support vector machine (SVM), or the like. The learning model may be stored in the first preparation unit 130, or may be generated by machine learning in the first preparation unit 130. For example, the learning model may be trained by using, as teacher data, the information in relation to the energy equipment to which new metering equipment was added by the user or the like in the past. As the information in relation to the energy equipment, at least one of: a type of the energy equipment; a type of another piece of the energy equipment which is connected to the input or the output of the energy equipment; the number of the branches included in the energy transmission path which is connected to the input or the output of the energy equipment; or the number of the plurality of pieces of energy equipment of the same type which are connected in parallel, may be used. The first preparation unit 130 may generate a learning model that extracts a feature amount from the information of the energy equipment; and outputs a higher priority as similarity is high (for example, a distance is close) between a feature amount of the energy equipment to which new metering equipment was added in the past, and a feature amount of the input energy equipment. The learning model may be generated for each type of the energy equipment or for each type of the energy. It should be noted that the learning model may be a model generated by machine learning by an external learning apparatus.

The first preparation unit 130 may acquire the user input to the first energy flow diagram. The first preparation unit 130 may cause the prepared first energy flow diagram to be displayed on the user apparatus 100 via the output unit 150, and acquire the user input to the first energy flow diagram via the acquisition unit 120. The first preparation unit 130 may acquire the user input to specify the equipment to be included in the second energy flow diagram, among the pieces of equipment shown in the first energy flow diagram. The first preparation unit 130 may acquire, by the user input, more detailed information on the information shown in the first energy flow diagram. The first preparation unit 130 may acquire, via the acquisition unit 120, additional information on the energy equipment and the metering equipment in the first energy flow diagram. The first preparation unit 130 may acquire an identifier or the like such as a product number of the energy equipment in the first energy flow diagram. In the first energy flow diagram, the first preparation unit 130 may acquire, via the acquisition unit 120, the user input indicating: an identifier such as a general name or a display name of the metering equipment; a measurement period of the metering equipment; calculation information (as an example, information for calculating a measurement value from a value detected by the metering equipment); a unit of the measurement value; a type of output data (analog or digital); and others. The first preparation unit 130 may acquire the user input to provide additional energy equipment on the energy transmission path. Depending on the energy transmission path, the energy is consumed while the energy passes through it, and thus it is possible to indicate the energy consumption by the additional energy equipment in the second energy flow diagram.

The first preparation unit 130 may cause the first energy flow diagram including the new metering equipment, to be displayed on the user apparatus 100 via the output unit 150, and acquire the user input to the new metering equipment in the first energy flow diagram via the acquisition unit 120. For example, according to acquiring the user input to delete at least one of the pieces of new metering equipment, the first preparation unit 130 may update the first energy flow diagram by deleting the new metering equipment.

The first preparation unit 130 may supply the information of the user input together with the first energy flow diagram to the second preparation unit 140.

In S230, the second preparation unit 140 prepares the second energy flow diagram in accordance with the first energy flow diagram prepared by the first preparation unit 130 and the user input. The second preparation unit 140 may prepare the second energy flow diagram including the information that is indicated by the user input to the first energy flow diagram. The second preparation unit 140 may prepare the second energy flow diagram which graphically shows: the connection relationships between the energy equipment, the energy transmission path, and the metering equipment; and more detailed information than the first energy flow diagram. The second preparation unit 140 may prepare the second energy flow diagram which graphically shows calculation information of the metering equipment. The second preparation unit 140 may automatically add, between the adjacent pieces of new metering equipment on the second energy flow diagram, virtual energy equipment to indicate an amount of consumption by the energy transmission path.

The second preparation unit 140 may prepare the second energy flow diagram which displays unspecified equipment, and acquire the user input to the unspecified equipment. The second preparation unit 140 may display, in the second energy flow diagram, the unspecified equipment for which more detailed information is not specified than in the first energy flow diagram, for example, by indicating a blank block containing no information or an unspecified status in a block (as an example, describing "unspecified" or the like in a rectangular block). The second preparation unit 140 may cause the second energy flow diagram, which displays the unspecified equipment, to be displayed on the user apparatus 100 via the output unit 150, and acquire the user input to the unspecified equipment via the acquisition unit 120. According to acquiring the user input to the unspecified equipment, the second preparation unit 140 may update the second energy flow diagram to show the information acquired by the user input.

The second preparation unit 140 may prepare, together with the second energy flow diagram, an input point list indicating the information in relation to data of each piece of the metering equipment. For each piece of metering equipment included in the second energy flow diagram, the second preparation unit 140 may prepare the input point list indicating at least one of: identification information such as an identifier, a general name, or a display name; a measurement period of the metering equipment; calculation information of a measurement value; a unit of the measurement value; or a type of output data. The second preparation unit 140 may further prepare the input point list indicating the measurement value of each piece of metering equipment. The second preparation unit 140 may prepare the input point list from the information acquired via the user input to the first energy flow diagram.

In S240, the output unit 150 may cause the second energy flow diagram and the input point list to be displayed on the user apparatus 100. The second preparation unit 140 may acquire the measurement value from each piece of metering equipment in real time via the acquisition unit 120, and cause the acquired measurement value to be displayed in the input point list. The output unit 150 may cause the first energy flow diagram to be displayed on the user apparatus 100, together with the second energy flow diagram and the input point list.

The preparation apparatus 110 of the present embodiment can prepare the energy flow diagram in two stages, and thus it is possible to efficiently prepare the energy flow diagram for FEMS with a high precision, by an interaction with the user. This makes it possible for the user to generate a production energy flow in which energy system information is added to a processing flow of production information, and it becomes possible to prepare the processing flow from a viewpoint of the energy and an amount of CO₂ emissions.

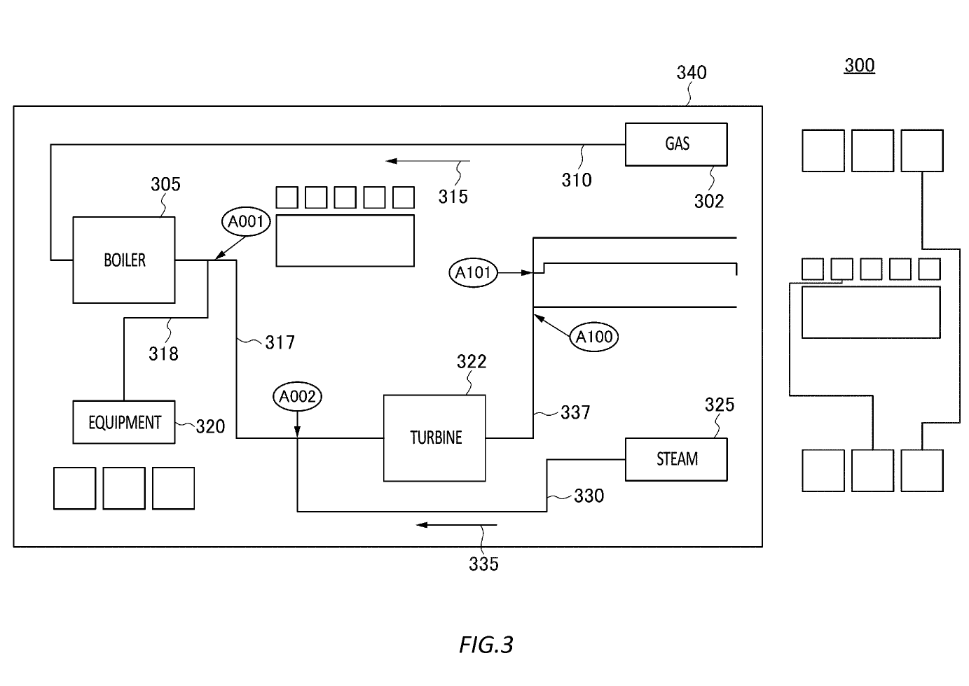

FIG. 3 shows an example of a layout diagram 300 which is acquired by the preparation apparatus 110 of the present embodiment. The layout diagram 300 in FIG. 3 is a layout diagram in relation to an energy flow in which a gas is converted into electricity to be supplied. In the layout diagram 300 in FIG. 3, marks are associated by the user input with a type of the energy equipment, the flow direction of the energy, and the branch of the energy transmission path.

In the layout diagram 300, an energy transmission path 310 (gas piping) is connected from energy equipment 302 which is a gas source, to energy equipment 305 (a boiler). An arrow mark 315 indicating the flow direction of the energy is associated with the energy transmission path 310. An energy transmission path 317 is connected between the energy equipment 305 (the boiler) and energy equipment 322 (a turbine), and has two branches A001, A002. The symbols A001 and A002 are identifiers of the branches, respectively. The branch A001 is connected to energy equipment 320 (equipment). The branch A002 is connected to energy equipment 325 which generates steam. An energy transmission path 330 is connected between the branch A002 and the energy equipment 325, and is associated with an arrow mark 335 indicating the flow direction of the energy. The energy equipment 322 (the turbine) is connected to an energy transmission path 337 on an output side which has branches A100, A101, and the energy transmission path 337 has an output end to which a plurality of pieces of energy equipment (not shown) are connected in parallel. In the layout diagram 300, a partial region is specified as a selection range 340 by the user input.

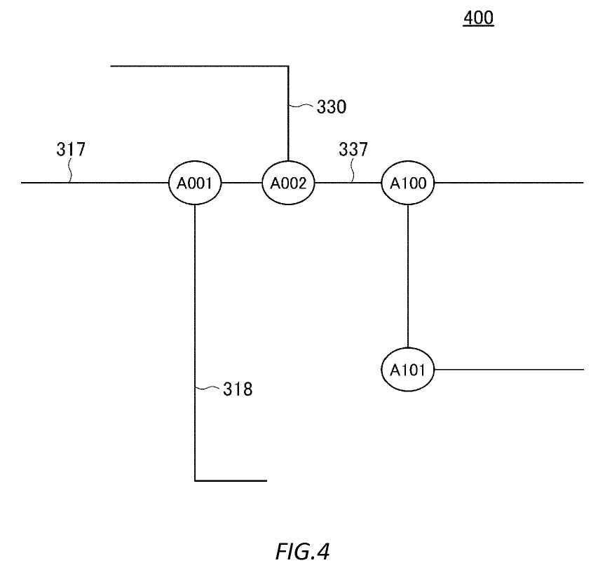

FIG. 4 shows an example of a branch layout diagram 400 which is acquired by the preparation apparatus 110 of the present embodiment. The branch layout diagram 400 shows only energy transmission paths 317, 318, 330, 337; and the branches A001, A002, A100, A101. The branch layout diagram 400 is a diagram showing the branches A001, A002, A100, A101; and the energy transmission paths 317, 318, 330, 337 which are connected to the respective branches A001, A002, A100, A101. The acquisition unit 120 may acquire the data of the branch layout diagram 400, together with the layout diagram 300.

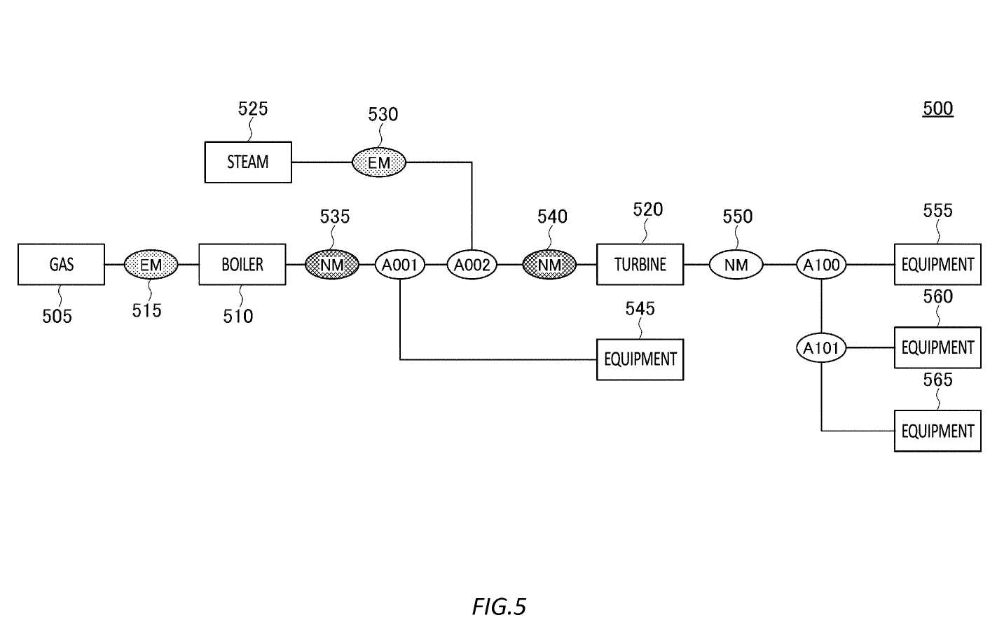

FIG. 5 shows an example of a first energy flow diagram 500 which is prepared by the preparation apparatus 110 of the present embodiment. In the first energy flow diagram 500, energy equipment 505 is displayed as a "gas", and indicates the energy equipment 302; and energy equipment 510 is displayed as a "boiler", and indicates the energy equipment 305. The metering equipment 515 is displayed as "EM", and indicates existing metering equipment acquired for the layout diagram 300 by the user input. Energy equipment 520 is displayed as a "turbine", and indicates the energy equipment 322. Metering equipment 535 is displayed as "NM", and indicates new metering equipment which measures output energy of the energy equipment 510. Metering equipment 530 is displayed as "EM", and indicates existing metering equipment acquired for the layout diagram 300 by the user input. Metering equipment 540 is displayed as "NM", and indicates new metering equipment which measures input energy to the energy equipment 520. Energy equipment 545 is displayed as "equipment", and indicates the energy equipment 320. Metering equipment 550 is displayed as "NM", and indicates new metering equipment which measures output energy of the energy equipment 520. Energy equipment 555, energy equipment 560, and energy equipment 565 indicate energy equipment connected in parallel to the output end of the energy flow.

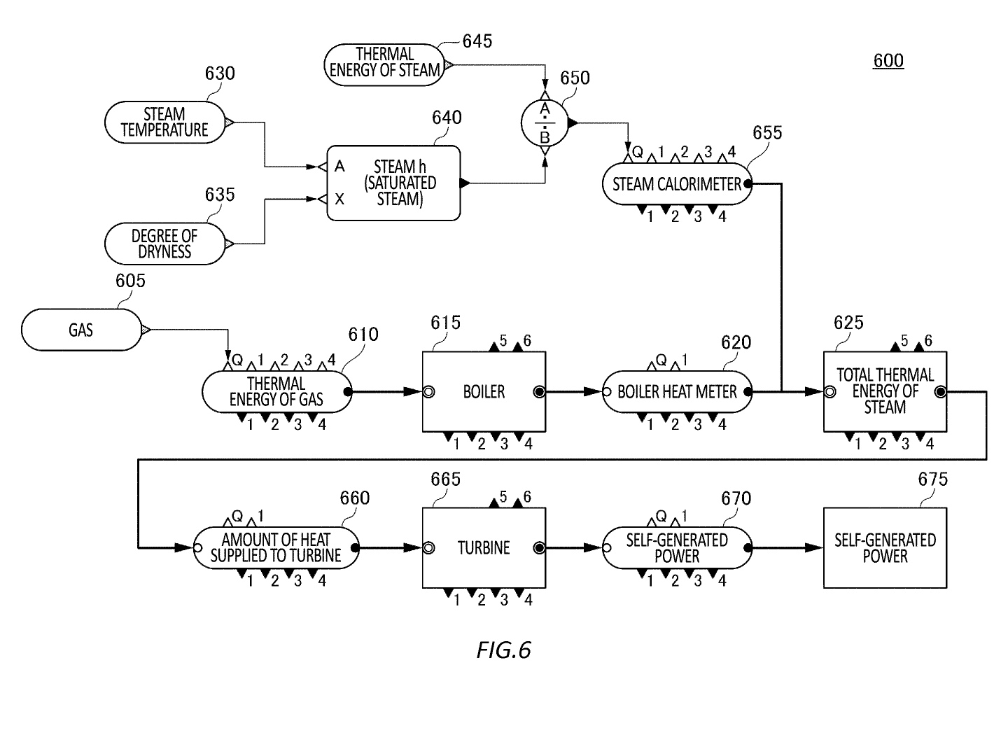

FIG. 6 shows an example of a second energy flow diagram 600 which is prepared by the preparation apparatus 110 of the present embodiment. In the second energy flow diagram 600, each piece of equipment is connected by the energy transmission path.

In the second energy flow diagram 600, energy equipment 605 is displayed as a "gas", and indicates the energy equipment 505 in the first energy flow diagram 500. The energy equipment 605 is connected to metering equipment 610, and is associated with information such as information of a gas supply company, and a gas fee, via the user input. The metering equipment 610 is displayed as "thermal energy of gas", and indicates the metering equipment 515 in the first energy flow diagram 500. The metering equipment 610 measures an amount of gas that is supplied from the energy equipment 605, the gas fee, or the like. Energy equipment 615 is displayed as a "boiler", and indicates the energy equipment 510. Metering equipment 620 is displayed as a "boiler heat meter", and indicates the metering equipment 535 in the first energy flow diagram 500. The metering equipment 620 can measure an amount of steam or the like that is output from the energy equipment 615. A block 630, a block 635, a block 640, a block 645, and a block 650 indicate calculation blocks of water vapors which are acquired for the energy equipment 525 of the first energy flow diagram 500, by the user input; and are displayed instead of the energy equipment 525. The block 630 is associated with a steam temperature; the block 635 is associated with a degree of dryness; the block 645 is associated with thermal energy of steam; and the block 640 and the block 650 are associated with functions that are applied to input values, and can display calculation results of the functions. Metering equipment 655 is displayed as a "steam calorimeter", and indicates the metering equipment 530. The metering equipment 655 can measure the thermal energy of steam or the like from values that are supplied from the block 630, the block 635, the block 640, the block 645, and the block 650.

Energy equipment 625 displays a "total thermal energy of steam", and is associated with a function that sums the thermal energy of steam input from two energy transmission paths. The energy equipment 625 is acquired by the user input to the first energy flow diagram 500. Metering equipment 660 is displayed as an "amount of heat supplied to turbine", and indicates the metering equipment 540. The metering equipment 660 measures a parameter in relation to the energy that is input to the energy equipment 665 (the thermal energy of steam, or the like). Energy equipment 665 is displayed as a "turbine", and indicates the energy equipment 520. Metering equipment 670 is displayed as "self-generated power", and indicates the metering equipment 550. The metering equipment 670 measures a parameter of the energy that is output from the energy equipment 665 (an amount of power or the like). Energy equipment 675 is displayed as "self-generated power", and indicates the pieces of energy equipment 555, 560, 565.

Each piece of metering equipment shown in the second energy flow diagram 600 may be associated with a function that outputs the corresponding measurement value, and display the measurement value by a selection by the user input on the second energy flow diagram 600. The measurement value may be a value acquired via a server from a meter installed in an actual plant, a terminal of the user, or the like. A white triangle of each piece of equipment shown in the second energy flow diagram 600 indicates a data input, and a black triangle indicates a data output of the calculation result or the like.

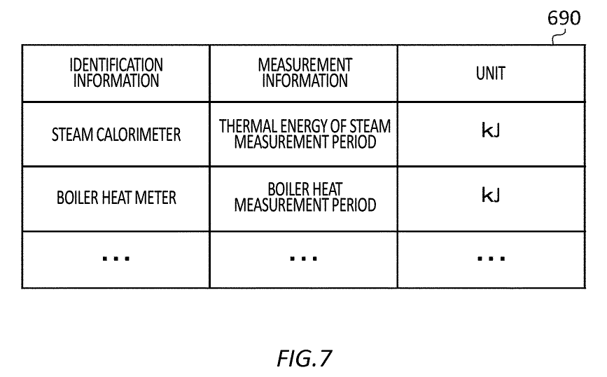

FIG. 7 shows an example of an input point list 690 which is prepared by the preparation apparatus 110 of the present embodiment. The input point list 690 may be a table showing the information of the metering equipment. In the input point list 690, for the metering equipment 655, as the identification information, the display name "steam calorimeter" is shown; as the measurement information, the thermal energy of steam that is a measurement target, the measurement period of the metering equipment 655, and the like are shown; and as a unit, "kJ" that is a unit of the thermal energy of steam is shown. In the input point list 690, for the metering equipment 620, as the identification information, a display name "boiler heat meter" is shown; as the measurement information, boiler heat that is a measurement target, the measurement period of the metering equipment 620, and the like are shown; and as a unit, "kJ" that is a unit of the boiler heat is shown. The output unit 150 may cause the input point list 690 to be displayed on the user apparatus 100, together with the second energy flow diagram 600.

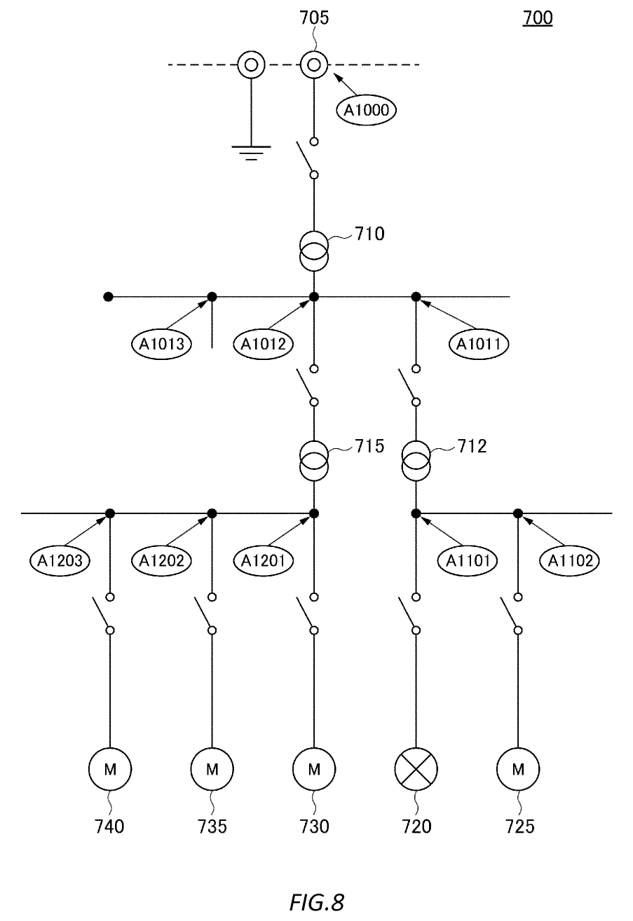

FIG. 8 is an example of a layout diagram 700 which schematically shows a single-line diagram. Energy equipment 705 is a power receiving apparatus such as a distribution board, and is a branch A1000 to the power system. Pieces of energy equipment 710, 712, 715 indicate transformers. Pieces of energy equipment 720, 725, 730, 735, 740 are either lighting equipment or production equipment, and indicate output ends of the energy transmission path extending from the energy equipment 705. The layout diagram 700 shows a plurality of branches A1011, A1012, A1013, A1101, A1102, A1201, A1202, A1203 in the energy transmission path. The preparation apparatus 110 may acquire the information of the equipment and the branch in the layout diagram 700, via the user input.

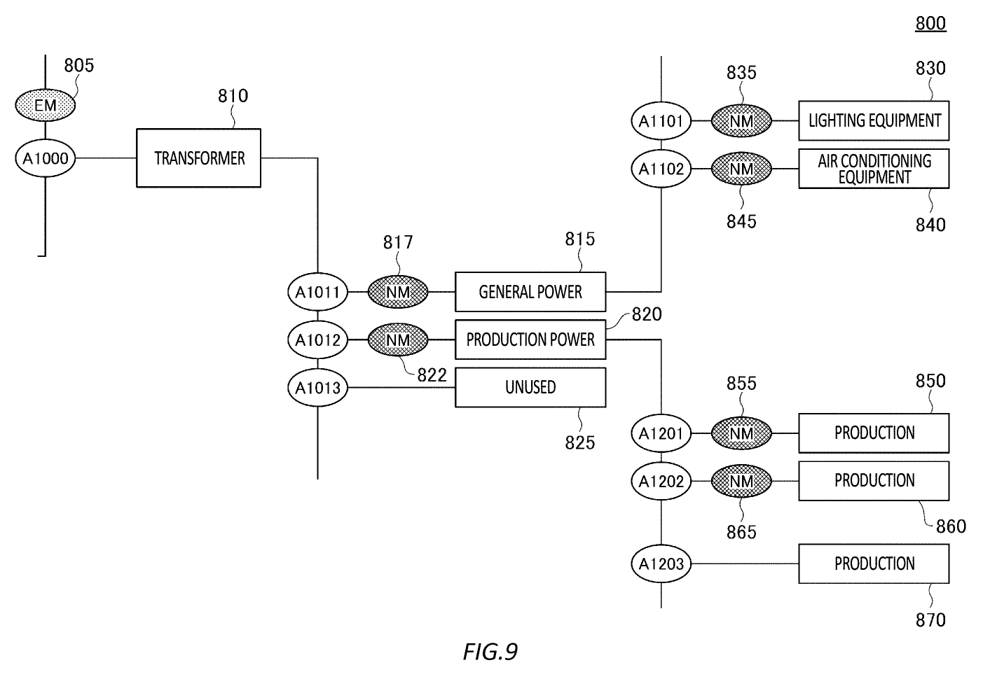

FIG. 9 shows an example of a first energy flow diagram 800 which is prepared from the layout diagram 700 by the preparation apparatus 110 of the present embodiment. The first energy flow diagram 800 shows existing metering equipment 805 (a power meter or the like) on the upstream side of the branch A1000. The first energy flow diagram 800 shows energy equipment 810 (a transformer), energy equipment 815 (general power), energy equipment 820 (production power), and energy equipment 825 (unused). The energy equipment 815 indicates the energy equipment 712 for supplying the power to the general equipment such as lighting equipment, and the energy equipment 820 indicates the energy equipment 715 for supplying the power to the production equipment such as a motor. The energy equipment 825 is displayed as "unused" to indicate that there is no equipment connected on the downstream side of the branch A1013. The first energy flow diagram 800 shows pieces of metering equipment 817, 822, 835, 845, 855, 865 that are pieces of new metering equipment. The first energy flow diagram 800 shows pieces of energy equipment 830, 840 (lighting equipment and air conditioning equipment) which are connected to the energy equipment 815, and are connected in parallel to each other. The first energy flow diagram 800 shows pieces of energy equipment 850, 860, 870 (production) which are connected to the energy equipment 820, and are connected in parallel to each other.

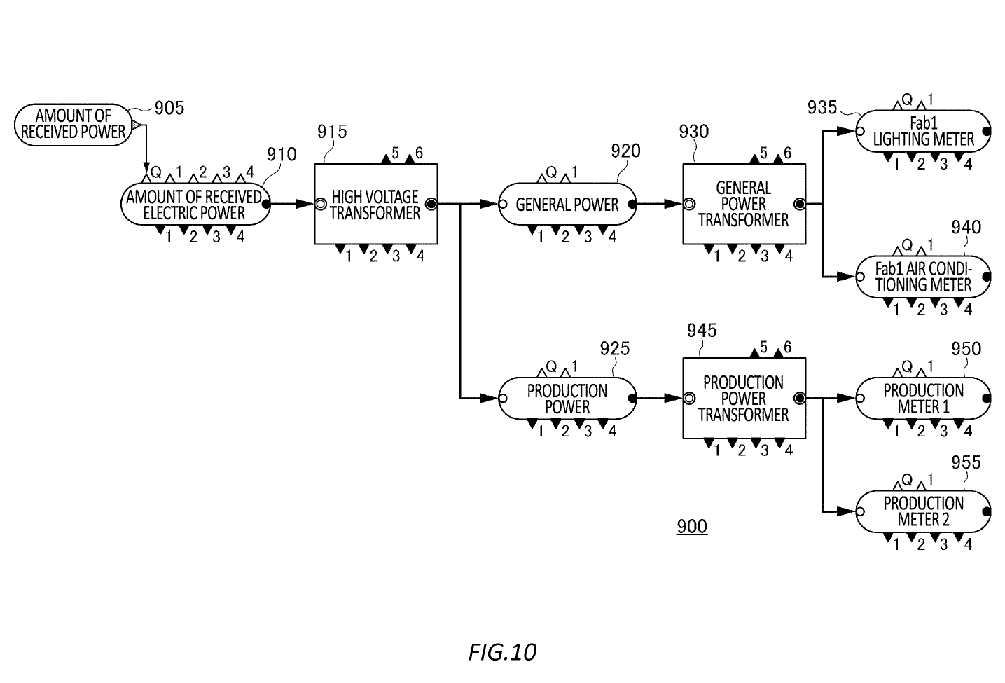

FIG. 10 shows an example of a second energy flow diagram 900 which is prepared from the first energy flow diagram 800 by the preparation apparatus 110 of the present embodiment. The second energy flow diagram 900 shows more detailed information acquired for the first energy flow diagram 800 via the user input. A block 905 indicates an amount of power received from the power system; and metering equipment 910 outputs an amount of power in accordance with the amount of received power, and indicates the metering equipment 805. Energy equipment 915 is displayed as a "high voltage transformer", and indicates the energy equipment 810. Metering equipment 920 is displayed as the "general power", and indicates the metering equipment 817. Metering equipment 925 is displayed as the "production power", and indicates the metering equipment 822. Energy equipment 930 is displayed as a "general power transformer", and indicates the energy equipment 815. Energy equipment 945 is displayed as a "production power transformer", and indicates the energy equipment 820. Pieces of metering equipment 935 and 940 connected in parallel are displayed as a "lighting meter", and an "air conditioning meter", respectively, and indicate the pieces of metering equipment 835 and 845. Pieces of metering equipment 950 and 955 connected in parallel are displayed as a "production meter 1", and a "production meter 2," respectively, and indicate the pieces of metering equipment 855 and 865.

Various embodiments of the present invention may be described with reference to flowcharts and block diagrams, where blocks may represent (1) stages of processes in which operations are executed or (2) sections of apparatuses responsible for executing operations. Certain stages and sections may be implemented by a dedicated circuit, a programmable circuit supplied together with computer-readable instructions stored on computer-readable media, and/or processors supplied together with computer-readable instructions stored on computer-readable media. The dedicated circuit may include digital and/or analog hardware circuits, and may include integrated circuits (IC) and/or discrete circuits. The programmable circuit may include a reconfigurable hardware circuit including logical AND, logical OR, logical XOR, logical NAND, logical NOR, and other logical operations, a memory element or the like such as a flip-flop, a register, a field programmable gate array (FPGA) and a programmable logic array (PLA), or the like.

A computer-readable medium may include any tangible device that can store instructions to be executed by a suitable device, and as a result, the computer-readable medium having instructions stored thereon includes a product including instructions that can be executed in order to create means for executing operations specified in the flowcharts or block diagrams. Examples of the computer-readable medium may include an electronic storage medium, a magnetic storage medium, an optical storage medium, an electromagnetic storage medium, a semiconductor storage medium, and the like. More specific examples of the computer-readable medium may include a FLOPPY (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disc (DVD), a BLU-RAY (registered trademark) disc, a memory stick, an integrated circuit card, and the like.

The computer-readable instruction may include: an assembler instruction, an instruction-set-architecture (ISA) instruction; a machine instruction; a machine dependent instruction; a microcode; a firmware instruction; state-setting data; or either a source code or an object code described in any combination of one or more programming languages, including an object oriented programming language such as Smalltalk (registered trademark), JAVA (registered trademark), C++, or the like, and a conventional procedural programming language such as a "C" programming language or a similar programming language.

The computer-readable instructions may be provided for a processor or programmable circuit of a general purpose computer, special purpose computer, or other programmable data processing apparatuses such as a computer locally or via a wide area network (WAN) such as a local area network (LAN), the Internet, or the like, and execute the computer-readable instructions in order to create means for executing the operations designated in flowcharts or block diagrams. Examples of the processor include a computer processor, a processing unit, a microprocessor, a digital signal processor, a controller, a microcontroller, and the like.

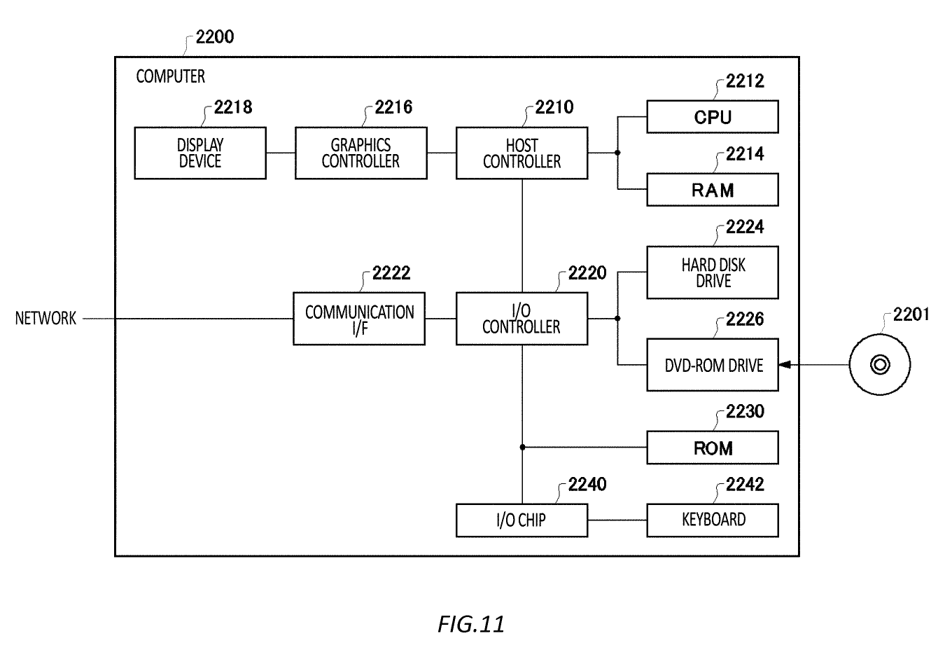

FIG. 11 shows an example of a computer 2200 in which a plurality of aspects of the present invention may be embodied entirely or partially. A program installed in the computer 2200 can cause the computer 2200 to function as an operation associated with the apparatuses according to the embodiments of the present invention or as one or more sections of the apparatuses, or can cause the operation or the one or more sections to be executed, and/or can cause the computer 2200 to execute a process according to the embodiments of the present invention or a stage of the process. Such programs may be executed by a CPU 2212 to cause the computer 2200 to perform specific operations associated with some or all of the blocks in the flowcharts and block diagrams described in the present specification.

The computer 2200 according to the present embodiment includes the CPU 2212, an RAM 2214, a graphics controller 2216, and a display device 2218, which are mutually connected by a host controller 2210. The computer 2200 also includes input/output units such as a communication interface 2222, a hard disk drive 2224, a DVD-ROM drive 2226, and an IC card drive, which are connected to the host controller 2210 via an input/output controller 2220. The computer also includes legacy input/output units such as an ROM 2230 and a keyboard 2242, which are connected to the input/output controller 2220 via an input/output chip 2240.

The CPU 2212 operates according to programs stored in the ROM 2230 and the RAM 2214, thereby controlling each unit. The graphics controller 2216 acquires image data generated by the CPU 2212 in a frame buffer or the like provided in the RAM 2214 or in itself, and causes the image data to be displayed on the display device 2218.

The communication interface 2222 communicates with other electronic devices via a network. The hard disk drive 2224 stores a program and data used by the CPU 2212 in the computer 2200. The DVD-ROM drive 2226 reads the program or the data from a DVD-ROM 2201 and provides the program or the data to the hard disk drive 2224 via the RAM 2214. The IC card drive reads the program and the data from the IC card, and/or writes the program and the data to the IC card.

The ROM 2230 stores therein a boot program and the like executed by the computer 2200 at the time of activation, and/or a program that depends on the hardware of the computer 2200. The input/output chip 2240 may also connect various input/output units to the input/output controller 2220 via a parallel port, a serial port, a keyboard port, a mouse port, or the like.

The program is provided by a computer-readable medium such as the DVD-ROM 2201 or the IC card. The program is read from a computer-readable medium, installed in the hard disk drive 2224, the RAM 2214, or the ROM 2230 which are also examples of the computer-readable medium, and executed by the CPU 2212. The information processing written in these programs is read by the computer 2200 and provides cooperation between the programs and the above-described various types of hardware resources. The apparatus or method may be constituted by implementing operations or processing of information according to use of the computer 2200.

For example, when communication is performed between the computer 2200 and an external device, the CPU 2212 may execute a communication program loaded in the RAM 2214 and instruct the communication interface 2222 to perform communication processing based on processing written in the communication program. Under the control of the CPU 2212, the communication interface 2222 reads transmission data stored in a transmission buffer processing region provided in a recording medium such as the RAM 2214, the hard disk drive 2224, the DVD-ROM 2201, or the IC card, transmits the read transmission data to the network, or writes reception data received from the network in a reception buffer processing region or the like provided on the recording medium.

In addition, the CPU 2212 may cause the RAM 2214 to read all or a necessary part of a file or database stored in an external recording medium such as the hard disk drive 2224, the DVD-ROM drive 2226 (DVD-ROM 2201), the IC card, or the like, and may execute various types of processing on data on the RAM 2214. Then, the CPU 2212 writes the processed data back in the external recording medium.

Various types of information such as various types of programs, data, tables, and databases may be stored in a recording medium and subjected to information processing. The CPU 2212 may execute, on the data read from the RAM 2214, various types of processing including various types of operations, information processing, conditional judgement, conditional branching, unconditional branching, information retrieval/replacement, or the like described throughout the present disclosure and specified by instruction sequences of the programs, and writes the results back to the RAM 2214. In addition, the CPU 2212 may retrieve information in a file, a database, or the like in the recording medium. For example, when a plurality of entries, each having an attribute value of a first attribute associated with an attribute value of a second attribute, are stored in the recording medium, the CPU 2212 may retrieve, out of the plurality of entries, an entry with the attribute value of the first attribute specified that meets a condition, read the attribute value of the second attribute stored in the entry, and thereby acquiring the attribute value of the second attribute associated with the first attribute meeting a predetermined condition.

The programs or software modules described above may be stored in a computer-readable medium on the computer 2200 or near the computer 2200. In addition, a recording medium such as a hard disk or an RAM provided in a server system connected to a dedicated communication network or the Internet can be used as a computer-readable medium, thereby providing a program to the computer 2200 via the network.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as "first" or "next" for the sake of convenience in the claims, specification, and drawings, it does not necessarily mean that the process must be performed in this order.

What is claimed is:

1. An apparatus comprising:
at least one processor, wherein
the at least one processor
acquires information of a layout diagram in relation to one or more pieces of energy equipment which generate or consume energy and one or more energy transmission paths which are connected to the energy equipment,
selects equipment to be included in a first energy flow diagram, from the layout diagram, and
outputs, based on the selected equipment, information of the first energy flow diagram which shows the energy equipment, the energy transmission path, and one or more pieces of metering equipment which measure parameters in relation to the energy.

2. The apparatus according to claim 1, wherein
the at least one processor extracts the energy equipment for which the metering equipment corresponding to the energy equipment is not installed, and prepares a proposal for one or more pieces of new metering equipment in the first energy flow diagram.

3. The apparatus according to claim 2, wherein
the at least one processor prepares the proposal for new metering equipment, based on at least one of information or an allowable cost of the energy equipment extracted by the at least one processor.

4. The apparatus according to claim 3, wherein
the at least one processor uses a learning model that outputs the proposal for new metering equipment according to an input of information in relation to the energy equipment, and prepares the proposal for new metering equipment in accordance with the energy equipment extracted by the at least one processor.

5. The apparatus according to claim 3, wherein
the at least one processor prepares the proposal for new metering equipment based on another energy equipment which is connected to an input or an output of the energy equipment extracted by the at least one processor.

6. The apparatus according to claim 3, wherein
the at least one processor prepares the proposal for new metering equipment based on a number of branches of the energy transmission path.

7. The apparatus according to claim 3, wherein
the at least one processor prepares the proposal for new metering equipment based on a number of a plurality of pieces of the energy equipment extracted by the at least one processor, of a same type connected in parallel.

8. The apparatus according to claim 1, wherein
the at least one processor
acquires a user input to the layout diagram, and
selects the equipment to be included in the first energy flow diagram, based on the user input.

9. The apparatus according to claim 8, wherein
the at least one processor extracts the energy equipment for which the metering equipment corresponding to the energy equipment is not installed, and prepares a proposal for one or more pieces of new metering equipment in the first energy flow diagram.

10. The apparatus according to claim 8, wherein
the at least one processor
acquires a user input to the first energy flow diagram, and
outputs information of a second energy flow diagram, based on the user input to the first energy flow diagram and the first energy flow diagram.

11. The apparatus according to claim 1, wherein
the at least one processor
acquires a plurality of layout diagrams, each of which is the layout diagram,
selects, in the plurality of layout diagrams, equipment to which a common mark is attached, as equipment to be included in the first energy flow diagram, and
combines pieces of equipment to which the common mark is attached in the plurality of layout diagrams, and outputs information of the first energy flow diagram.

12. The apparatus according to claim 11, wherein
the at least one processor extracts the energy equipment for which the metering equipment corresponding to the energy equipment is not installed, and prepares a proposal for one or more pieces of new metering equipment in the first energy flow diagram.

13. The apparatus according to claim 11, wherein
the at least one processor
acquires a user input to the first energy flow diagram, and
outputs information of a second energy flow diagram, based on the user input to the first energy flow diagram and the first energy flow diagram.

14. The apparatus according to claim 1, wherein
the at least one processor
acquires a user input to the first energy flow diagram, and
outputs information of a second energy flow diagram, based on the user input to the first energy flow diagram and the first energy flow diagram.

15. The apparatus according to claim 14, wherein
the at least one processor
prepares the second energy flow diagram which displays unspecified equipment, and
acquires a user input to the unspecified equipment.

16. The apparatus according to claim 14, wherein
the at least one processor prepares, together with the second energy flow diagram, an input point list indicating information in relation to data of each piece of the metering equipment.

17. A method which is executed by at least one processor, the method comprising:
acquiring information of a layout diagram in relation to one or more pieces of energy equipment which generate or consume energy and one or more energy transmission paths which are connected to the energy equipment;
selecting equipment to be included in a first energy flow diagram, from the layout diagram; and
outputting, based on the selected equipment, information of the first energy flow diagram which shows the energy equipment, the energy transmission path, and one or more pieces of metering equipment which measure parameters in relation to the energy.

18. A non-transitory computer-readable medium having recorded thereon a program that causes a computer to:
acquire information of a layout diagram in relation to one or more pieces of energy equipment which generate or consume energy and one or more energy transmission paths which are connected to the energy equipment;
select equipment to be included in a first energy flow diagram, from the layout diagram; and
output, based on the selected equipment, information of the first energy flow diagram which shows the energy equipment, the energy transmission path, and one or more pieces of metering equipment which measure parameters in relation to the energy.
